(19) United States
(12) Patent Application Publication
(10) Pub. No.: US 2016/0345468 A1
(43) Pub. Date: Nov. 24, 2016

(54) KINETIC HEAT SINK WITH STATIONARY FINS

(71) Applicant: COOLCHIP TECHNOLOGIES, INC., Boston, MA (US)

(72) Inventors: Lino A. Gonzalez, Somerville, MA (US); Pramod Chamarthy, Plano, TX (US); Florent Nicolas Séverac, Oakland, CA (US)

(21) Appl. No.: 14/784,429

(22) PCT Filed: Mar. 17, 2014
(86) PCT No.: PCT/US14/30162

§ 371 Date: Oct. 14, 2015

Related U.S. Application Data
(60) Provisional application No. 61/816,450, filed on Apr. 26, 2013.

(51) Int. Cl. H05K 7/20; H01L 23/367; H01L 23/473; H01L 23/467

(52) U.S. Cl. CPC H05K 7/20409; H01L 23/467; H01L 23/3672; H01L 23/3677; H05K 7/20009; H05K 7/20218; H01L 23/473

(57) ABSTRACT

A heat-dissipating apparatus has a base structure, a rotating structure, and stationary fins. The base structure has a first heat-conducting surface and a second heat-conducting surface to conduct heat therebetween. The first heat-conducting surface is mountable to a heat-generating component. The rotating structure rotatably couples with the base structure and has a movable heat-extraction surface facing the second heat-conducting surface across a fluid gap. The rotating structure has rotating fins that channels a heat-transfer fluid when the rotating structure rotates from a region of a thermal reservoir in communicating with the rotating structure to another area of the thermal reservoir. The stationary fins extend from the second heat-conducting surface or the housing and are in the path of fluid flow between two areas of the thermal reservoir.

### PRIORITY

This patent application claims priority from provisional U.S. patent application No. 61/816,450, filed Apr. 26, 2013 entitled, “KINETIC HEAT SINK WITH STATIONARY FINS,” and naming Lino A. Gonzalez, Pramod Chamarthy, and Florent Nocolas Séverac as inventors, the disclosure of which is incorporated herein, in its entirety, by reference.

### TECHNICAL FIELD

The present invention relates to heat-extraction and dissipation devices and methods and, more particularly, kinetic heat sinks for use with electronic components.

### BACKGROUND ART

During operation, electric circuits and devices generate waste heat. To operate properly, the temperature of electric circuits and devices typically should be within a certain range. Commonly, the temperature of an electric device is regulated using a heat sink physically mounted to the electric device.

Rather than using a heat sink, those in the art have recently moved toward a more active component cooling approach—a kinetic heat sink. At a high level, a kinetic heat sink typically has a base that couples with the electronic device, and a rotating thermal mass with integrated fluid-directing structures (such as fins, fan blades, or impellers). The rotating part more efficiently draws heat from the base, cooling the electronic device using a smaller footprint.

Kinetic heat sinks may be configured to direct fluid flow, which is especially suitable for certain cooling application. Fluid refers to both liquid and gas (e.g., air). This often requires a housing positioned over the base and rotating thermal mass. The housing, however, adds another design constraint; namely, it typically requires a reasonably large clearance between the rotating portion and the housing to mitigate the flow impedance it may create. This increased-clearance consequently increases the size of the overall device, at least partly negating the benefit of the smaller footprint provided by a kinetic heat sink.

### SUMMARY OF ILLUSTRATIVE EMBODIMENTS

In accordance with illustrative embodiments of the invention, a heat-dissipating apparatus has a base structure with a first heat-conducting surface and a second heat-conducting surface to conduct heat therebetween. The first heat-conducting surface is mountable to a heat-generating component. The heat-dissipating apparatus also has a rotating structure rotatably coupled with the base structure. This rotating structure has a movable heat-extraction surface facing the second heat-conducting surface across a fluid gap. The fluid gap may have lowered thermal-resistance characteristics when the rotating structure rotates. The rotating structure has rotating fins that channel thermal medium (i.e., forms fluid flow), when the rotating structure rotates, from a region (i.e., first area) of a thermal reservoir in communication with the rotating structure to another region (i.e., second area) of the thermal reservoir. The base structure has stationary fins extending from the second heat-conducting surface. The fins are in the path of fluid flow between the first area and the second area of the thermal reservoir. Fluid refers to both liquid and gas (e.g., air).

The heat-dissipating apparatus may have a housing that is fixably coupled to the base structure and encloses the rotating structure and the stationary fins. The housing may have an inlet and an outlet along the path of fluid flow between the first area and the second area of the thermal reservoir. The heat-dissipating apparatus may have a second set of stationary fins external to the housing. The second set of stationary fins may be located at the mouth of the inlet and/or outlet.

The housing may be shaped to promote or channel fluid flow. For example, the housing may be shaped as a spiral or a shell. The stationary fins (internal to the housing or external) may be shaped as blades, pegs, or cylinders. The stationary fins may be a grid structure, such as a honeycomb or metal foams. The fins may be configured to achieve a specified heat transfer density, a specified noise characteristic, or a specified flow rate when operating in conjunction with the kinetic heat sink.

In accordance with another embodiment of the invention, a method of operating a heat-dissipating apparatus provides a heat-dissipating apparatus with a base structure, a rotating structure, and stationary fins. The base structure has a first heat-conducting surface and a second heat-conducting surface to conduct heat therebetween. The first heat-conducting surface is mountable to a heat-generating component. The rotating structure rotatably couples with the base structure and has a movable heat-extraction surface facing the second heat-conducting surface across a fluid gap. The rotating structure has rotating fins that channel a heat-transfer fluid when the rotating structure rotates from a region (i.e., first area) of a thermal reservoir in communicating with the rotating structure to another area (i.e., second area) of the thermal reservoir. The stationary fins extend from the second heat-conducting surface or the housing and are in the path of fluid flow between the first area and the second area of the thermal reservoir. The method also includes varying the speed of rotation of the rotating structure to control an amount of heat transfer from the stationary fins in the path of the fluid flow and the heat transfer from the rotating fins.

### BRIEF DESCRIPTION OF THE DRAWINGS

The foregoing features of embodiments will be more readily understood by references to the following detailed description, taken with reference to the accompanying drawings, in which:

FIG. 1 schematically shows a cross-sectional view of a heat-dissipating apparatus according to an illustrative embodiment.

FIG. 2 illustrates an operation of the heat-dissipating apparatus of FIG. 1.

FIG. 3A schematically shows a cross-sectional view of a heat-dissipating apparatus according to another embodiment that outputs a guided-flow.

FIG. 3B schematically shows a cross-sectional view of a heat-dissipating apparatus according to an alternate embodiment.

FIGS. 4A-F schematically show stationary fin shapes according to the various embodiments.

FIG. 5 illustrates the heat-transfer performance of a heat-dissipating apparatus according to an illustrative embodiment.

FIG. 6 illustrates a comparison of the heat-transfer coefficient between stationary fins and the impellers of kinetic heat sinks.

FIG. 7 schematically shows a kinetic heat sink with stationary fins according to an illustrative embodiment.

FIG. 8A schematically shows an exploded view of the kinetic heat sink of FIG. 7.

FIG. 8B schematically shows the kinetic heat sink of FIG. 7 according to an alternate embodiment.

FIG. 8C schematically shows the kinetic heat sink of FIG. 8B according to an alternate embodiment.

FIG. 9 illustrates thermal-resistance characteristics of a kinetic heat sink with stationary fins according to an illustrative embodiment.

FIG. 10A schematically shows a kinetic heat sink with stationary fins according to another illustrative embodiment that outputs a guided-flow.

FIG. 10B schematically shows a kinetic heat sink with stationary fins according to an alternative embodiment.

FIGS. 11A-D schematically show stationary fins layout patterns according to various embodiments.

FIG. 12 illustrates the relative velocity of fluid flow in the impeller channel portions of the embodiment of FIG. 7.

FIG. 13 illustrates the relative velocity of fluid flow across the embodiment of FIG. 7.

FIG. 14 is a schematic illustrating a kinetic heat sink with stationary fins according to an embodiment.

FIG. 15A is a plot illustrating device performance of the kinetic heat sink apparatus of FIG. 14.

FIG. 15B is a plot illustrating airflow performance of the kinetic heat sink apparatus of FIG. 14.

FIG. 16 is a method of operating a kinetic heat sink according to illustrative embodiments.

### DETAILED DESCRIPTION OF SPECIFIC EMBODIMENTS

Illustrative embodiments facilitate high-density heat transfer of a kinetic heat sink using stationary fins coupled directly to the base plate that secures the heat-generating element. In addition to improving heat transfer, this arrangement enables the kinetic heat sink to have a housing that provides a guided fluid flow and yet, maintain a relatively small footprint. Fluid refers to both liquid and gas (e.g., air). Details of various embodiments are discussed below.

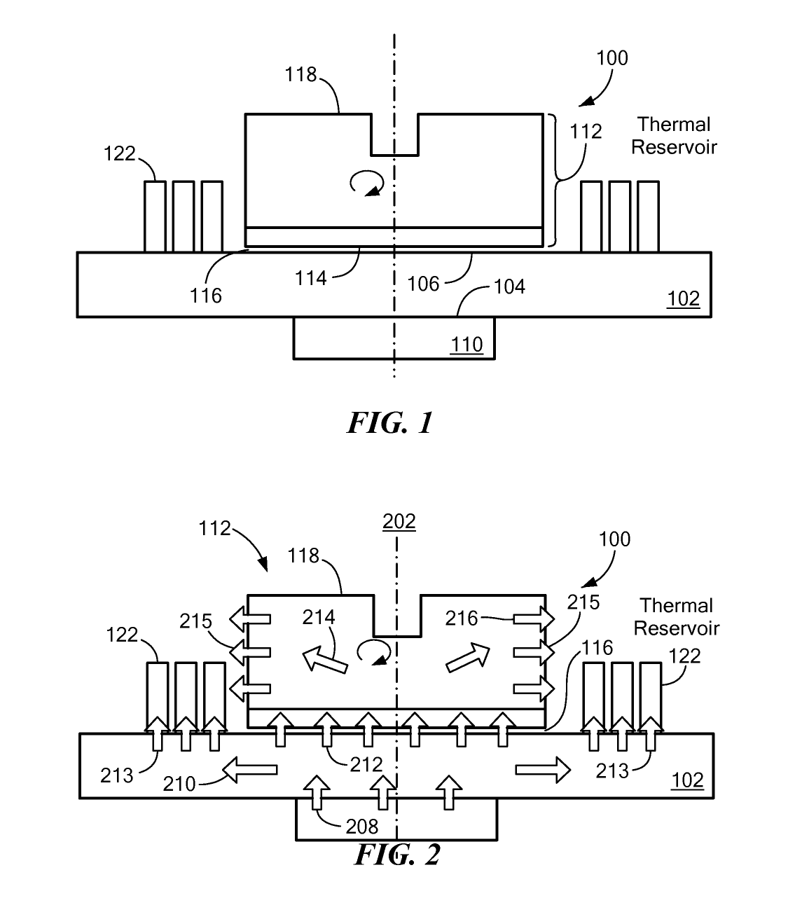

FIG. 1 schematically shows a cross-sectional view of a heat-dissipating apparatus 100 (also referred to as “kinetic heat sink 100”) according to illustrative embodiments of the invention. The heat-dissipating apparatus 100 has a base structure 102 with both a first heat-conducting surface 104 and a second heat-conducting surface 106 to conduct heat therebetween. The first heat-conducting surface 104 is mountable to a heat-generating component 110, such as an electronic device or component. For example, among other things, the component may include a resistive device, a printed circuit board, or an integrated circuit.

The heat-dissipating apparatus 100 has a rotating structure 112 rotatably coupled with the base structure 102. The rotating structure 112, which may be part of a rotor of an electric motor (not shown), has a movable heat-extraction surface 114 facing the second heat-conducting surface 106 across a fluid gap 116. In some embodiments, when the rotating structure 112 rotates during normal operation, the fluid gap 116 varies between about 10 um (micrometer) and about 20 um, thus having a thermal-resistance characteristic (e.g., less than 0.1 degree Celsius per Watt). Other embodiments form the fluid gap 116 to be larger or smaller. For example, in an alternate embodiment having the fluid gap 116 formed between vertically concentric fins protruding from the rotating and base structures 102, 112, the fluid gap 116 may be at least 50 microns or larger. In illustrative embodiments, the thermal resistance across the fluid gap 116 may decrease by more than half as a result of the rotation. The rotating structure 112 has rotating fins 118 that channel a thermal medium (i.e., fluid), when the rotating structure 112 rotates, from a region (i.e., first area) of a thermal reservoir communicating with the rotating structure 112 to another area (i.e., second area) of the thermal reservoir. As used herein, the rotating structure 112 may be referred to as an impeller.

In accordance with illustrative embodiments of the invention, the base structure 102 also has a set of stationary fins 122 extending from the second heat-conducting surface 106 to provide additional heat-dissipating surface areas. The stationary fins 122 are physical structures in the fluid flow path between the first area and the second area of the thermal reservoir. The rotating structure 112 provides the fluid flow to reject heat further from the stationary fins 122. The stationary fins 122, which, as shown, are in the direct path of fluid flow, also reject heat by natural convection.

The stationary fins 122 may be integral with the second heat-conducting surface 106—effectively part of the base structure 102. Alternatively, the stationary fins 122 may be removably connected with the base plate.

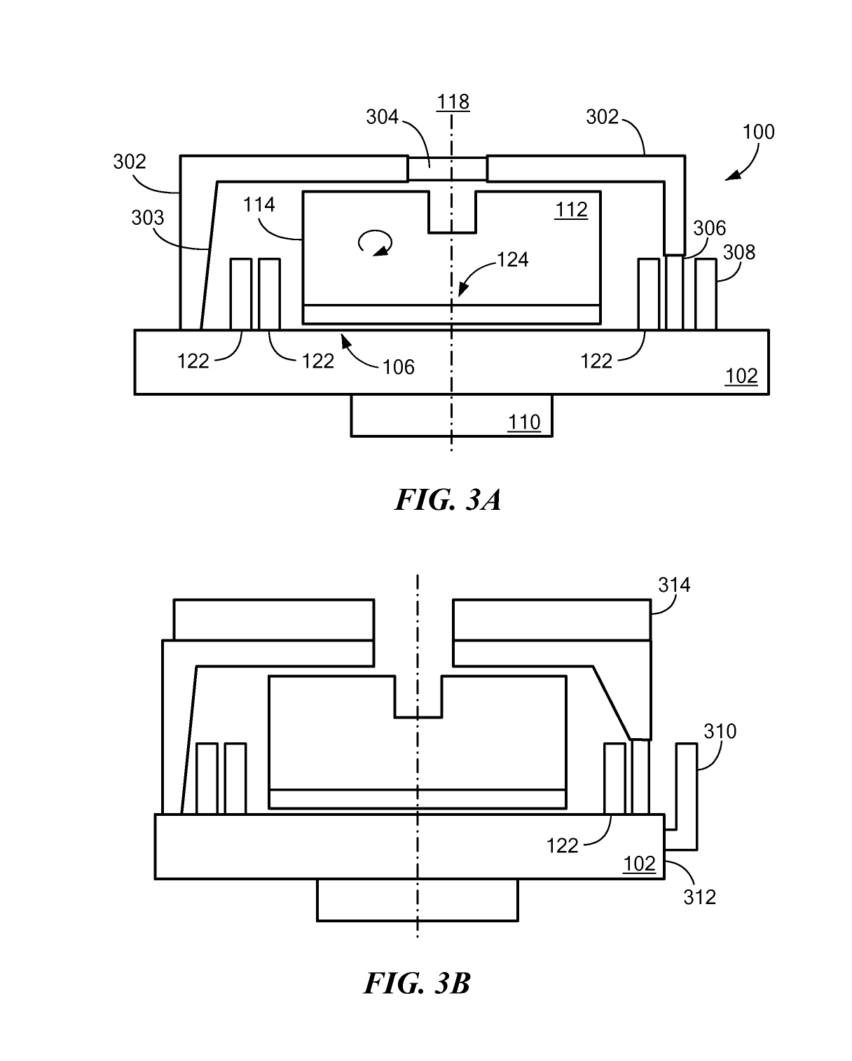

FIG. 2 illustrates an operation of the heat-dissipating apparatus of FIG. 1. In the figure, the rotating structure 112 rotates to channel the thermal medium from first area 202 of the thermal reservoir to another region (i.e., second area) of the thermal reservoir along a flow path. The fluid-flow may exit the rotating structure 112 in a radial direction. The rotating structure 112 may form a vortex at the first area 202. As fluid flows through the heat-dissipating apparatus 100 (e.g., across the rotating fins 118 of the rotating structure 112), a temperature gradient (i.e., ΔT) forms between the heat-generating component 110 and the solid volumes of the heat-dissipating apparatus 100. The temperature gradient provides a heat-transfer potential resulting in greater heat extraction between the solid volumes and heat rejection between the solid volume and transfer medium. Generally, the base structure 102 extracts heat (arrow 208) from the heat-generating component 110 and spreads the heat (arrow 210) across the base structure 102. As the heat spreads 210 across the base structure 102, a portion 212 of the heat is transferred to the rotating structure 112 across the fluid gap 116 and is rejected into the thermal reservoir by the rotating fins 118. Another portion of the heat 213 spreads through the stationary fins 122 and is rejected into the pre-heated 215 fluid being dispelled from the rotating structure 112.

At low rotation speeds, when the thermal-resistance characteristic across the fluid gap 116 is low relative to the thermal resistance of the stationary fins 122, the heat 212 being transferred and rejected by the rotating structure 112 is greater than the heat 213 being rejected by the stationary fins 122. As the rotation speed increases, the thermal-resistance characteristics of the stationary fins become lower than the combined resistance of the air gap 116 and rotating fins 118. This results in less of heat 212 being transferred from the base structure 102 to the rotating structure 112 and more of heat 213 being spread to the stationary fins 122.

Heat rejection through the rotating structure 112 is dependent on the thermal resistance of the fluid gap 116 and the thermal resistance of the rotating structure 112. Starting from rest, the thermal resistance of the fluid gap 116 is generally low in relation to the thermal resistance of the rotating structure 112 and the stationary fins 122. At higher speeds, the fluid gap 116 becomes a bottleneck in removing heat away from the base structure 102. The inventors realized that stationary fins 122 have no such limitations, as they do not require an air gap, and may therefore operate at higher efficiency (i.e., lower thermal resistance) at such higher rotation speed. Accordingly, stationary fins 122 provide a separate heat transfer and rejection mechanism from the rotating structure 112, which supplements the heat dissipating operation of the rotating structure 112, particularly at higher ranges of rotation speed.

Thermal reservoir refers to a space or environment having a relatively large thermal mass compared to a heat-dissipating apparatus and may include a thermal bath, or ambient air in which the heat-dissipating apparatus may sit. The heat-dissipating apparatus may operate in a thermal reservoir having varying temperature, which may occur, for example, in closed thermal systems.

As disclosed herein, the various embodiments of the heat-dissipating apparatus may be similar to the kinetic heat sink disclosed in U.S. Provisional Patent Application No. 61/66,868 having the title “Kinetic Heat Sink Having Controllable Thermal Gap” filed Jun. 26, 2012, and U.S. Provisional Patent Application No. 61/713,774 having title “Kinetic Heat Sink with Sealed Liquid Loop” filed Nov. 8, 2012. These patent applications are incorporated herein by reference in their entireties.

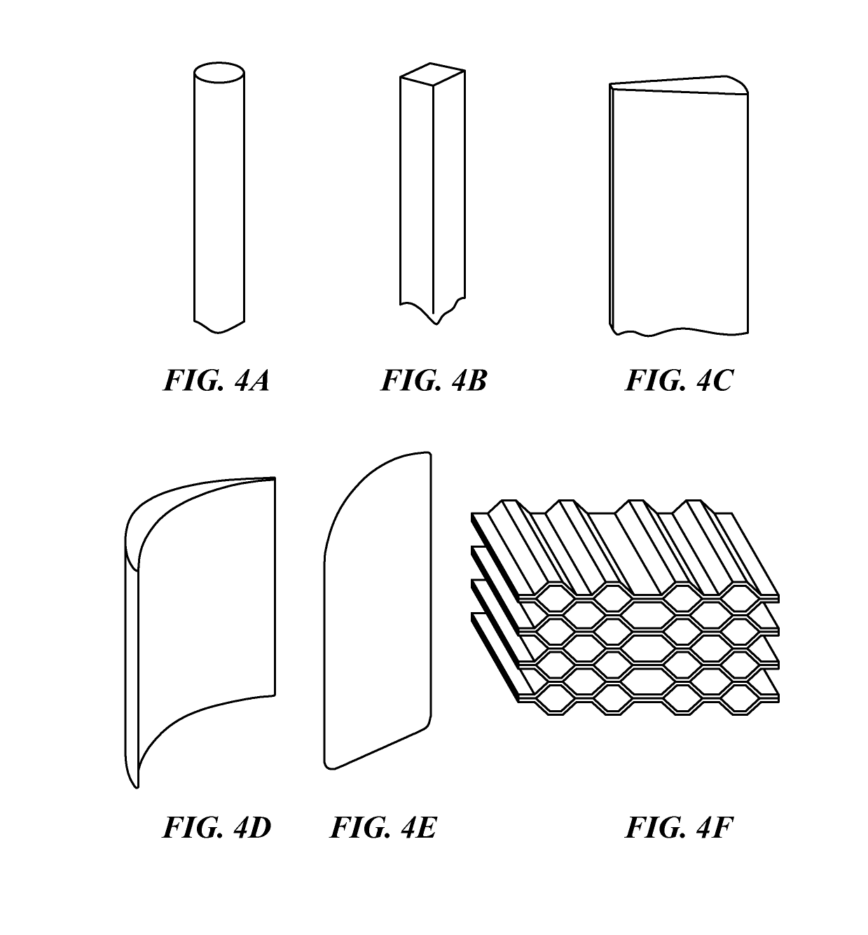

FIG. 3A schematically shows a cross-sectional view of a heat-dissipating apparatus 100 according to another embodiment that outputs a guided-flow.

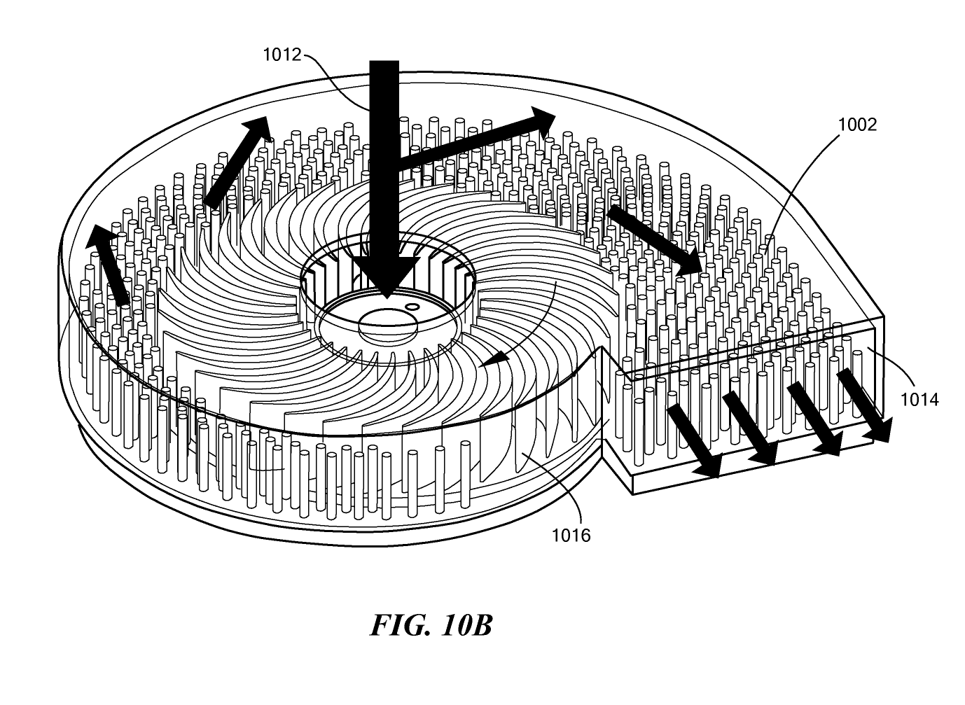

To output the guided-flow, the heat-dissipating apparatus 100 may have a housing 302 that encloses the rotating structure 112 and the stationary fins 122. In illustrative embodiments, the housing 302 is fixably coupled to the base structure 102. Alternatively, the housing 302 may be mounted to other static surfaces proximal to the heat-dissipating apparatus 100. The housing 302 may be shaped to promote or channel fluid flow 124, including, for example, a spiral or a shell (see for example, FIG. 10). The housing 302 may have angled internal surfaces 303 to enhance fluid flow.

Guided-flow output refers to movement of the transfer medium in a channeled manner (i.e., not radial in all direction). As discussed, the guided-flow output may be beneficial in certain cooling applications. For example, the guided-flow may be used to cool other devices convectively or to prevent the settling of dust particles on other heat-dissipating surfaces.

In addition to the stationary fins 122, the heat-dissipating apparatus 100 may have a second set of stationary fins 308 external to the housing 302 (referred to as “external stationary fins”). The second set of stationary fins 308 may be located at an inlet 304 of the housing 302 and/or an outlet 306 of the housing 302. The external stationary fins 308 may extend from the second heat-conducting surface 106 similar to the stationary fins 122, or alternatively extend from the housing 302 or the sidewalls 312 of the base structure 102. For example, external out-take stationary fins 310 form at output 306, and external intake stationary fins 314 may be formed at the mouth of the inlet 304. FIG. 3B schematically shows a cross-sectional view of a heat-dissipating apparatus 100 according to such alternate embodiments.

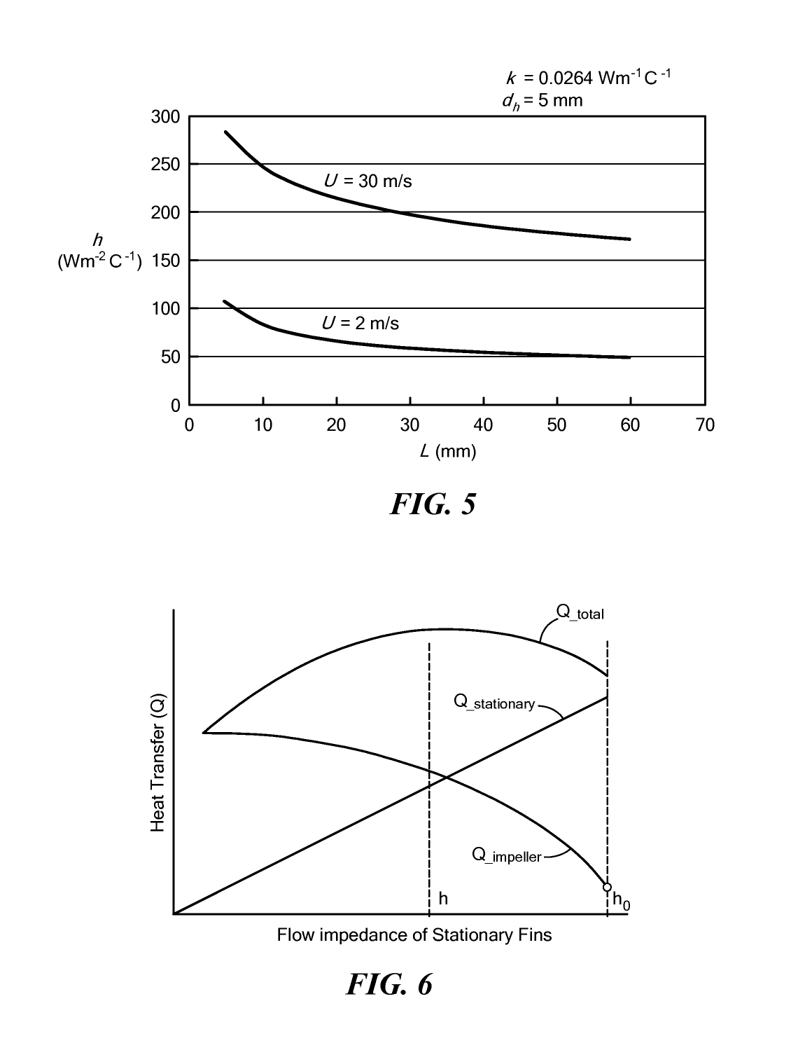

The stationary fins (internal 122 or external 308, 310, 314) provide surface area for heat transfer and may be shaped to guide, impede, or minimally affect flow. FIGS. 4A-E schematically show stationary fin shapes according to the various embodiments. Among other things, the stationary fins may be shaped as a blade, a peg, or a cylinder. The stationary fins may collectively form a grid structure, such as a honeycomb. The figures show stationary fin shapes, including a cylinder (FIG. 4A), a diamond (FIG. 4B), a rudder (FIG. 4C), a curved blade (FIG. 4D), a fan blade (FIG. 4E), and a honeycomb grid (FIG. 4F). The fins may be configured to achieve a specified heat-transfer density, a specified noise characteristic, or a specified flow rate.

### Heat-Transfer Density

Stationary fins beneficially provide additional heat-transfer surface area, allowing for higher heat-transfer density. The additional heat transfer is particularly beneficial where a housing is employed—in such a design, the stationary fins use volume generally not accessible to the rotating structure (e.g., heat sink impeller). Thus, for the same cooling capabilities, a smaller diameter rotating structure or cooler device footprint results.

Conventional heat sinks (e.g., fan-cooled heat sinks (FCHS)) generally include a fan component mounted to a heat sink, which in turn is mounted to a heat source. The heat sink extracts heat from the heat source while the fan rotates, generating airflow, which rejects the extracted heat to the ambient air. Kinetic heat sinks combine the benefits of a heat sink and fan into a single component. In doing so, illustrative embodiments produce higher fluid velocity across its heat rejection surfaces (e.g., fins) for the same rotational speed. Thus, in kinetic heat sinks configured in accordance with illustrative embodiments are expected to have a higher heat-transfer coefficient.

More specifically, the heat transfer capacity of a heat sink from a heat rejection surface (e.g., fins) to a transfer fluid (e.g., air) may be expressed as Q, as in Equation 1,

Q=hA·ΔT (Equation 1)

where the heat transferred (Q) is a function of effective heat-transfer coefficient (h), heat-transfer area (A), and temperature difference between the heat rejection surface and the transfer fluid (ΔT).

The effective heat-transfer coefficient (h) may be expressed as a function of the thermal conductivity of the transfer fluid (k), the Nusselt number (Nu), and the hydraulic diameter (Dₕ), as shown in Equation 2,

$$h = \frac{k}{{D}_{h}} Nu \qquad ( Equation 2 )$$

For an application where air is the transfer medium, k may be around 0.0264 Wm⁻¹ C⁻¹.

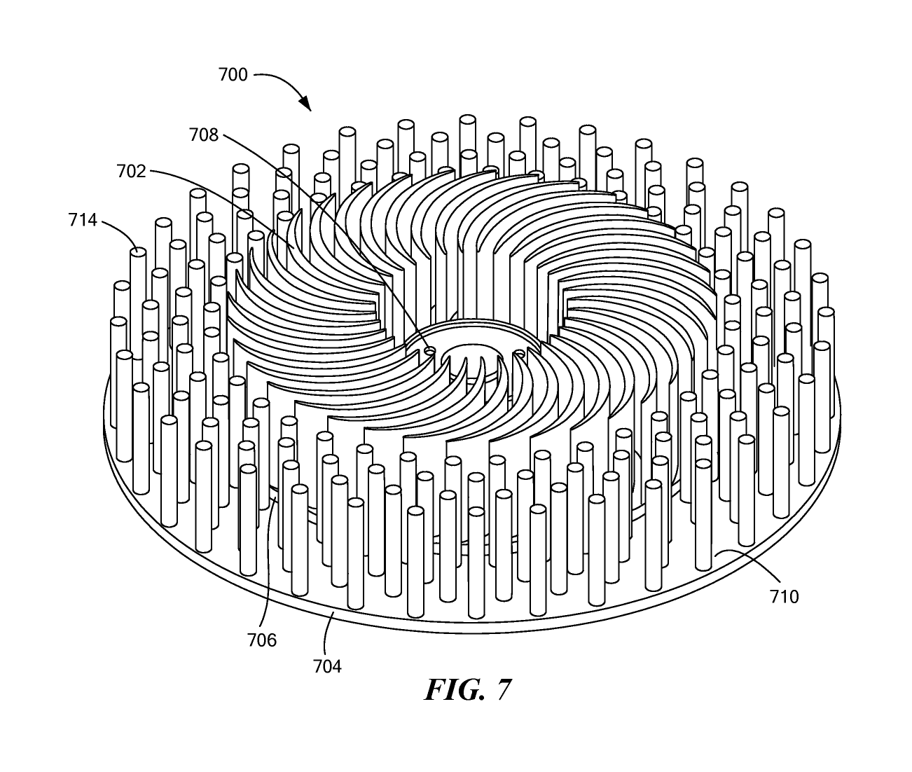

For example, a natural convection heatsink generally have an h value between 5 and 10 while a FCHS may have an h value between 50 and 150, which corresponds to laminar flow. A KHS may have an h value between 200 and 300, which corresponds to turbulent flow. FIG. 5 illustrates the heat-transfer coefficient for stationary fins and the rotating structures (i.e., impellers) of some kinetic heat sinks. For example, for a 55-millimeter channel formed by the impeller fins or the stationary fins, it is shown that increasing the relative fluid velocity 15 times (e.g., U=2 meter per second (m/s) to U=30 m/s) generally improves heat transfer three times (e.g., h=100 to h=300).

The additional surface area of stationary fins adds a second heat-transfer component (Q_{—stationary}) to the heat-transfer component of the kinetic heat sink (Q_{—impeller}). Equation 3 is the total heat transfer (Q_{—total}) of a kinetic heat sink with stationary fins.

Q_{—total}=Q_{—impeller}+Q_{—stationary} (Equation 3)

Equation 3 may be expanded using Equation 1 resulting in Equation 4.

Q_{—total}=h_{—impeller}Aᵢₘₚₑₗₗₑᵣ·ΔTᵢₘₚₑₗₗₑᵣ+h_{—stationary}A_{stationary}·ΔT_{stationary} (Equation 4)

Stationary fins also add impedance to the flow of heat-transferring fluid, thereby reducing the heat-transfer coefficient of the kinetic portion of the heat sink. Thus, with stationary fins, the Nusselt number of the kinetic portion of the heat sink likely is lower than a kinetic heat sink without the stationary fins.

The inventors have discovered that the overall heat-transfer performance of the kinetic heat sink with stationary fins (Q_{—total}) may be increased with respect to a kinetic without the stationary fins. Though the stationary fins may reduce the heat-transfer capacity for the kinetic portion of the heat sink (Q_{—impeller}) in causing a lower fluid flow as a result of increasing air flow impedance, the overall heat-transfer performance may nevertheless increase as a result of having the additional heat-transfer capacity from the stationary fins (Q_{—stationary}). In other words, the stationary fins may provide higher cooling performance from having additional area for heat transfer (A_{—stationary}), which may be balanced with the impedance the stationary fins add to the operation of the device.

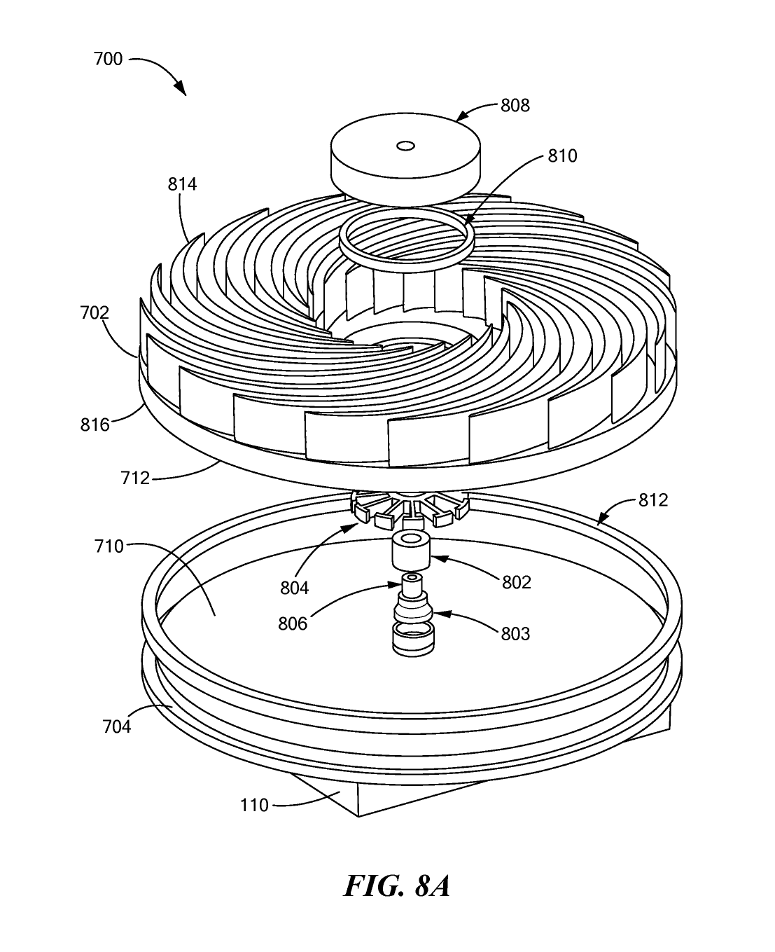

FIG. 6 illustrates heat-transfer performance of a heat-dissipating apparatus according to an illustrative embodiment. As flow impedance of the stationary fins increase, the heat-transfer performance of the stationary fins (Q_{—stationary}) also increases while the heat-transfer performance of the kinetic portion of the heat sink decreases (Q_{—impeller}). Consequently, an optimum stationary fin configuration maximizes the total heat-transfer performance.

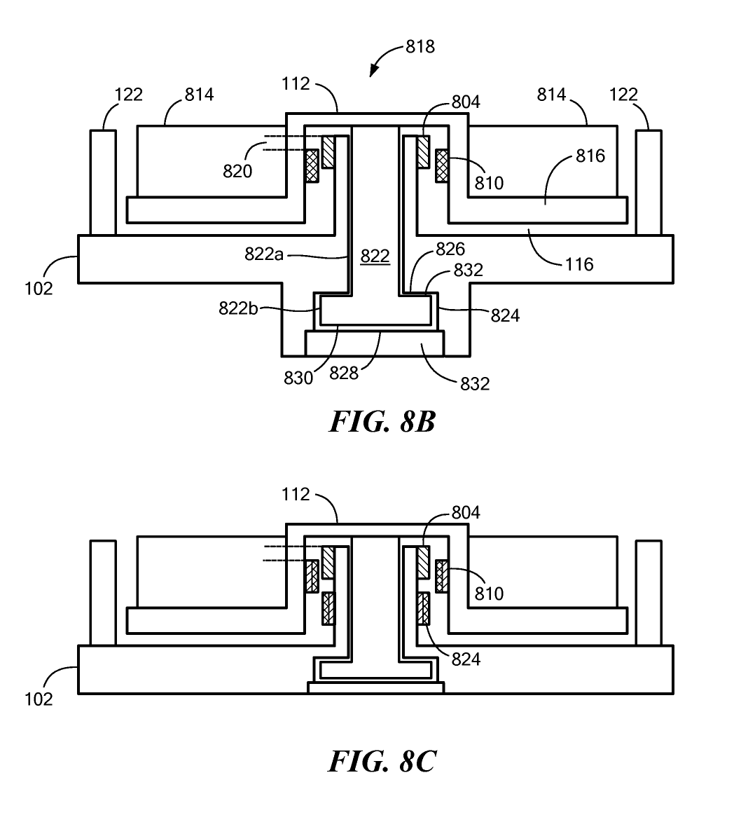

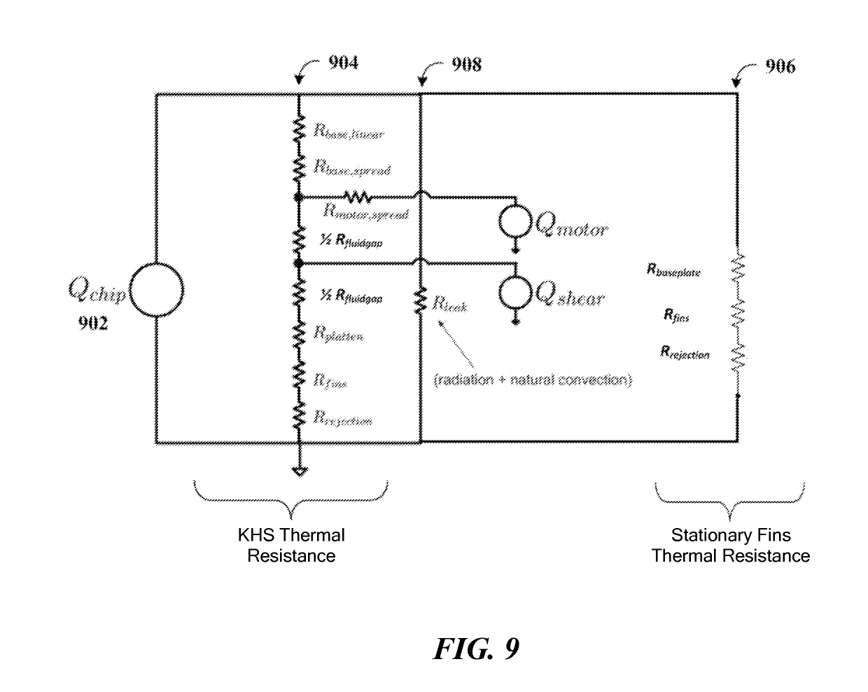

FIG. 7 schematically shows a kinetic heat sink 700 with stationary fins according to an illustrative embodiment. The kinetic heat sink 700 includes an impeller 702 rotatably coupled, via an electric motor 708, to a base structure 704 across a fluid gap 706. The base structure 704 has a heat-conducting surface 710 facing a heat extraction surface 712 (not shown—see FIG. 8A) of the impeller 702. A set of stationary fins 714 extend from the base structure 704 and surround the impeller 702. The set of stationary fins 714 are arranged in a grid pattern where each fin is equally spaced apart from other fins along the grid. The set of stationary fins 714 are shaped as cylindrical rods or pegs.

FIG. 8A schematically shows an exploded view of the kinetic heat sink 700 of FIG. 7. The stationary fins 714 are not shown to provide clearer view of the other components. According to this embodiment, the electric motor 708 includes an assembly having stationary components coupled to the base structure 704 and rotating components coupled to the impeller 702. The stationary components include a motor housing 802 and base housing 803 housing the rotor 806. The stationary components also include motor windings 804 to provide the rotating electromagnetic field to rotate the rotor 806. The rotating components include the rotor 806 fixably coupled to the impeller 702 via a clamp 808. The impeller 702 includes permanent magnets 810 that magnetically couple with the motor windings 804.

It should be apparent to those skilled in the art that the electric motor may be configured with various types of motors. For example, the electric motor may include: direct-current (DC) based motors such as brushed DC motors, permanent-magnet electric motors, brushless DC motors, switched reluctance motors, coreless DC motors, universal motors; or alternating-current (AC) based motors such as single-phase synchronous motors, poly-phase synchronous motors, AC induction motors, and stepper motors.

The kinetic heat sink may include an insert 812 fixably coupled to or near the outer perimeter base structure 704 to provide both low-friction contacts during start-ups and shock-absorption during operations. In illustrative embodiments, the impeller 702 includes a set of rectangular-curved fins 814 extending from a rotating plate 816. The rotating plate 816 may have two sides; namely, one that includes the heat extraction surface 712 and another that includes the fins 814. As indicated, the heat extraction surface 712 forms the fluid gap 706 with the heat-conducting surface 710 of the base structure 704. The fluid gap 706 may be less than 10 um when the kinetic heat sink 700 is at rest, and may vary between 10 um and 100 um during normal operation, preferably between 10 um and 20 um in some embodiments. In other embodiments, the fluid gap 706 may be zero when at rest. The fins 814 may form channels for fluid transfer medium to flow when the rotating structure 702 rotates.

FIG. 8B schematically shows a kinetic heat sink of FIG. 7 according to an alternate embodiment. Rather than or in addition to the insert 812, a kinetic heat sink 818 may be configured to use magnetic forces between the rotating structure 112 and the base structure 102 to provide minimum or reduced frictional contact at start-ups. The base structure 102 of the kinetic heat sink 818 may have the motor windings 804 (e.g., stator) fixably attached thereto, and the rotating structure 112 may have the permanent magnets 810 (i.e., rotor magnets) fixably attached thereto. The motor windings 804 may be positioned higher than the permanent magnets 810 (i.e., rotor magnets) in the axial direction to form an offset 820. The offset between the windings 804 and the magnets 810 may result in a magnetic attraction that produces an upward axial force on the rotor. The attraction may urge the rotating structure 112 to lift with respect to the base structure 102. The motor windings 804 may be positioned 100 um to 200 um higher than the magnets, preferably 140 um.

The base structure 102 and the rotating structure 112 may be configured to maintain the offset 820 during start-ups. The rotating structure 112 may include a rotor 822 configured to be seated within the base structure 102. The rotor 822 may include a shaft portion 822a and a widen portion 822b. The widen portion 822b may retains the rotor 822 within the base structure 102 and may include control features (e.g., fluid-dynamic bearings) to regulate the offset between the base structure 102 and the rotating structure 112. The base structure 102 may form a chamber 824 corresponding to the geometry of the rotor 822 for the rotor 822 to seat. The base structure 102 may include a retaining cap 832 to attach to a bore within the base structure 102 that forms the chamber 824.

The chamber 824 may include an upper thrust surface 826 and a lower thrust surface 828 as part of a fluid-dynamic bearing (also referred to as a counter thrust bearing assembly) that forms with the corresponding surfaces 830, 832 of rotor 822. As such, during operation (i.e., when the rotating structure 112 is rotating), the fluid-dynamic bearing may regulate the axial offset between the base structure 102 and the rotating structure 112. The rotating structure 112 may include a plate portion 834 that the rotating fins 118 fixably attached thereto. The plate portion 834 may include the movable heat-extraction surface 114 that form the fluid gap 116 with the second heat-conducting surface 106 of the base structure 102.

The windings 804 and magnets 810 may be configured to produce an attraction having magnetic strength sufficient to offset the weight of the rotating structure 112. For example, if the magnetic attraction force between the windings 804 and the magnet 810 is greater than the weight of the rotating structure 112, the upper thrust bearing surface 832 of the rotor 822 may make a contact with the upper thrust surface 826 of the chamber 824. As a result, an offset 836 (not shown) may form between the lower thrust surfaces 828, 830 of the fluid-dynamic bearing. At start-up, the offset 836 may vary between 5 um and 20 um. The contact at the upper thrust surface 826, 832 of the fluid-dynamic bearing in the embodiment may have a lower start-up friction than a contact between the first heat-conducting surface 104 and a second heat-conducting surface 106 resting thereupon.

The rotating structure 112 and the base structure 102 may include hard coatings between the heat-transfer surfaces to reduce wear, including the first heat-conducting surface 104 and a second heat-conducting surface 106. The coating may be 1 um to 5 um in thickness, preferably 2 um. The coating may be composed of diamond-like carbon (e.g., DLC), such as Titankote™. Of course, other hard coatings may be employed. The coatings may have thermal transfer properties similar to the base structure 102 and the rotating structure 112 to minimize resistance to thermal transfer.

The shaft portion 822a of the rotor 822 and the corresponding surface of the base structure 102 may include additional fluid-dynamic bearing features (not shown) to maintain centricity of the rotating structure 112, when rotating, with respect to the base structure 102.

FIG. 8C schematically shows the kinetic heat sink of FIG. 8B according to an alternate embodiment. In addition to the motor windings 804 and the permanent magnets 810, the kinetic heat sink 818 may include a second set of permanent magnets 824. The second permanent magnets 824 may be affixably attached to the base structure 102 and configured to produce a repulsive force with respect to the permanents magnets 810 of the rotating structure 112 when at rest. The second permanent magnets 824 may enable larger and heavier rotating structure 112 or reduce motor component sizes.

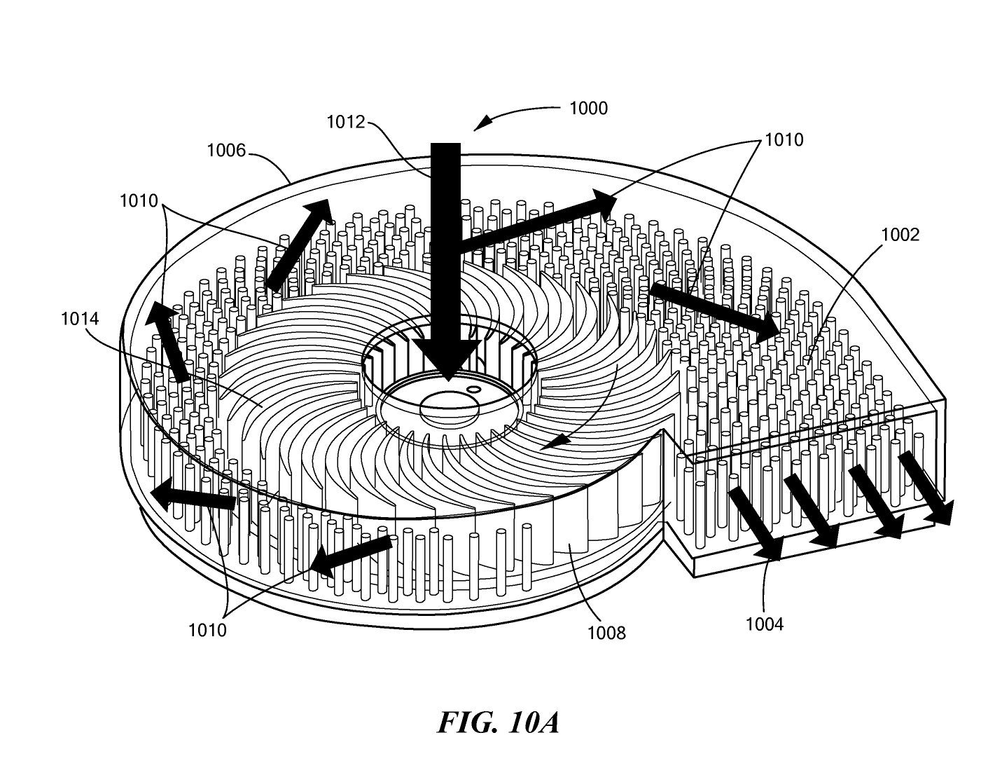

FIG. 9 illustrates thermal-resistance characteristics of a kinetic heat sink with stationary fins according to an illustrative embodiment. The heat-generating component 110 generates heat (Q_{chip} 902). This heat may dissipate to the thermal reservoir through the kinetic portion 904 of the kinetic heat sink, the stationary fins portion 906, and by natural convection or radiation 908. In an embodiment, the kinetic heat sink may dissipate between 40 Watt (W) and 130 W of heat (Q_{chip} 902) for a power draw of the motor between 3 W and 10 W. Of course, the kinetic heat sink may be configured to dissipate other amount of heat.

Table 1 provides examples of thermal-resistance characteristics of one embodiment of the kinetic heat sink of FIG. 9.

TABLE 1

| Parameter | Component | Value | |
|---|---|---|---|
| Q_{chip} | | 95 | W |
| Qₘₒₜₒᵣ | KHS | 2 | W |
| Qₛₕₑₐᵣ | KHS | 2 | W |
| R_{base, linear} | KHS | 0.003 | C/W |
| R_{base, spread} | KHS | 0.055 | C/W |
| R_{motor, spread} | KHS | 0.055 | C/W |
| R_{fluidgap} | KHS | 0.055 | C/W |
| Rₚₗₐₜₑₙ | KHS | 0.0025 | C/W |
| R_{fins} | KHS | 0.005 | C/W |
| R_{rejection} | KHS | 0.12 | C/W |
| Rₗₑₐₖ | Leakage | 6.40 | C/W |
| R_{rejection} | Stationary | 0.3 | C/W |
| R_{fins} | Stationary | 0.005 | C/W |
| R_{baseplate} | Stationary | 0.06 | C/W |

The thermal resistance of the kinetic portion 904 includes resistance across the base structure 704, the fluid gap 706, and the impeller 702, as well as from the impeller 702 to the thermal reservoir. The thermal resistance of the base structure 704 may be characterized as having a linear component (R_{base,linear}) and spreading component (R_{base,spread}) that is radial to the linear component. The heat generated by the electric motor 708 (Qₘₒₜₒᵣ) and by fluid gap 706 (Qₛₕₑₐᵣ) contributes to the overall heat to be removed by the kinetic heat sink. The heat contribution to the electric motor 708 and the fluid gap 706 may be modeled as internal heat sources (Qₛₕₑₐᵣ and Qₘₒₜₒᵣ) being passed through effective resistances R_{motor,spread} and R_{fluidgap}. The rotating plate 816 has a thermal resistance (Rₚₗₐₜₜₑₙ), and the fins 814 have a thermal resistance (R_{fins}). The heat rejection between the solid surfaces (of 702, 704) and the transfer medium has a thermal resistance (R_{rejection}).

In contrast to the kinetic portion 904 of the heat sink, the thermal resistance of the stationary fins 714 merely includes that of the baseplate (R_{baseplate}), the fins (R_{fins}), and the heat rejection (R_{rejection}).

FIG. 10A schematically shows a kinetic heat sink 1000 with stationary fins 1002 according to another embodiment that outputs a guided-flow 1004. Fluid enters through the inlet 1012 and travels through the channels 1014 within the impeller 1008. The impeller outputs fluid flow in a radial direction (see arrow 1010), and the housing 1006 channels or directs the radial fluid flow 1010 into a specified direction of the guided fluid flow 1004. The direction of the fluid flow is generally in an outward direction due to the centrifugal force exerted on the fluid from the rotation of the impeller 1008. The stationary fins 1002 allow for a smaller footprint housed cooling device. The impeller 1008 may be backwardly curved. Backwardly curved impellers are generally more stable and tolerable to mismatch in the impeller geometry for a given fluid flow.

FIG. 10B schematically shows a kinetic heat sink 1000 with stationary fins 1002 according to an alternative embodiment that outputs a guided-flow. The impeller of FIG. 10A may be forwardly curved. Similar to the backwardly curved impeller 1008, the direction of the fluid flow in a forwardly curved impeller 1016 is also generally in an outward direction due to the centrifugal force exerted on the fluid from the rotation of the impeller 1016. A forwardly curved impeller may be configured with smaller fins compared to backwardly curved fins of comparable footprints. A kinetic heat sink with forwardly-curved impellers may be configured to operate at a lower impeller rotation-speed to generate the same flow compared to a backwardly-curved-fin impeller. In an embodiment, a kinetic heat sink with low inertia is employed using forwardly-curved impellers. The centrifugal force that causes the outward flow direction of the impellers 1008, 1016 may be expressed as fᵣ=½ρrω², where ρ is the fluid density, r is the radial location of the force, and ω is the angular velocity.

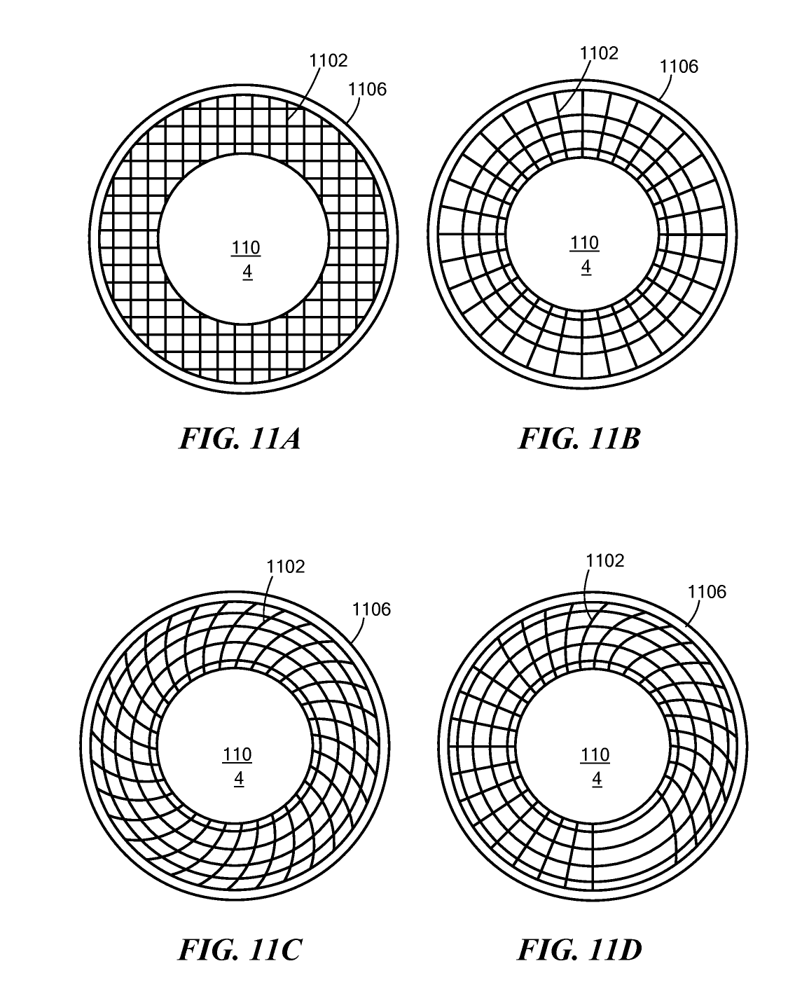

FIGS. 11A-D illustrate various stationary fin layout patterns. The intersections 1102 between the lines designate a stationary fin placed around an impeller 1104 and extending from the base structure 1106. The layout may include horizontal and vertical grid pattern, such as shown in FIG. 11A. The layout may alternatively be in radial pattern, such as shown in 11B. Alternatively, the layout may be have a radial component and an arc component, as shown in FIG. 11C. The layout may be asymmetrical, as shown in FIG. 11D. Of course, other layouts maybe employed. It should be apparent to those skilled in the art that the various stationary fins layout pattern may be applied to variously shaped heat dissipating apparatus.

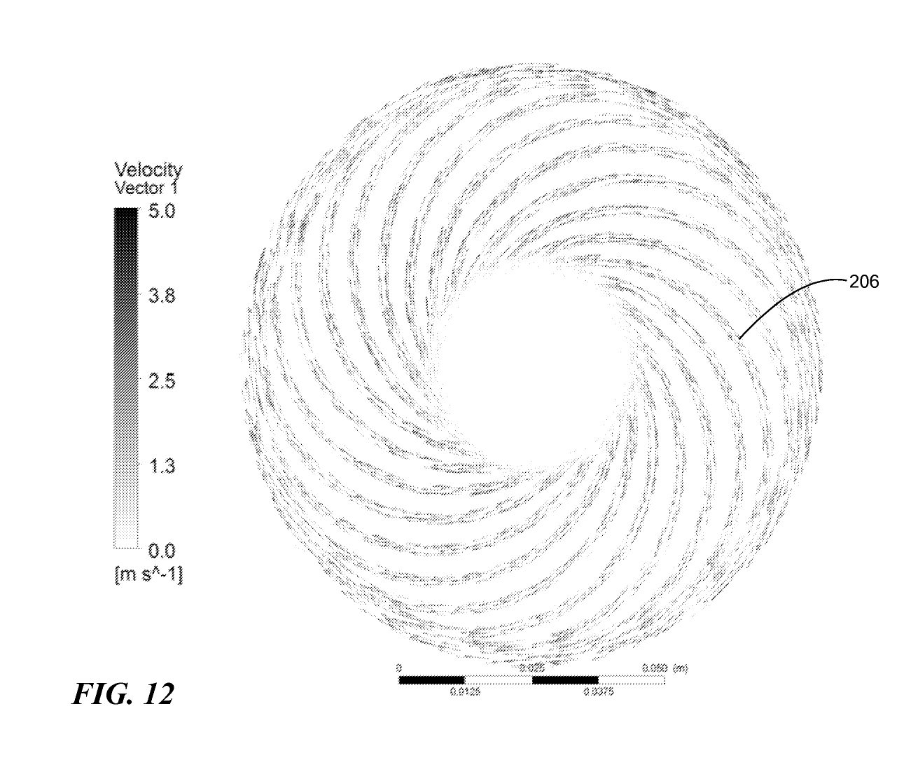

FIG. 12 illustrates relative velocity of fluid flow in the channels between the impeller 702 of the kinetic heat sink of FIG. 7. As fluid is drawn in from the top of the impeller 702 and flows over the length of the channel, the relative velocity of the fluid increases as a result of fluid entering channels formed between the fins and throughout the length of the channels. Since the channels have constant thickness, by conservation of mass the fluid relative velocity increases as more fluid enters along the length of the channel. The relative velocity (also referred to as the velocity distribution) within the channels is a function of the shape of the fins, which defines the cross-sectional shape of the channels. As shown in FIG. 12, at approximately 1000 RPM, a fluid vector is formed. As the rotation speed increases, the fluid flow increases in a generally linear manner. For some kinetic heat sinks, at 5000 RPM rotational speed, the max fluid velocity is approximately 25 meters per second.

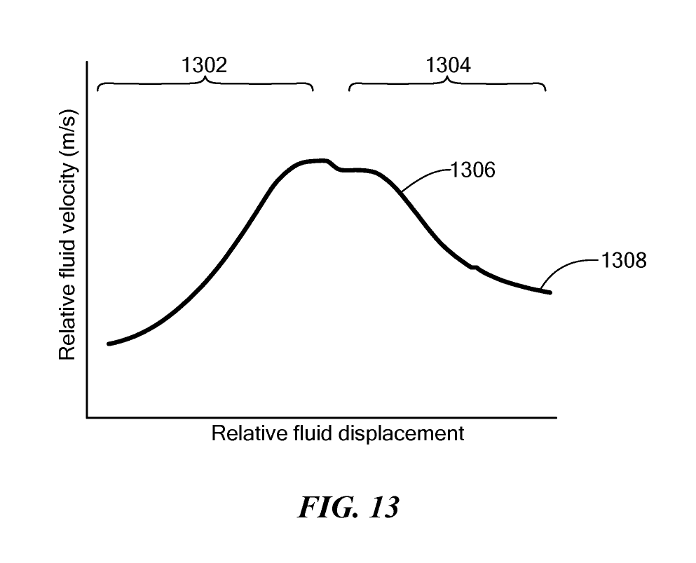

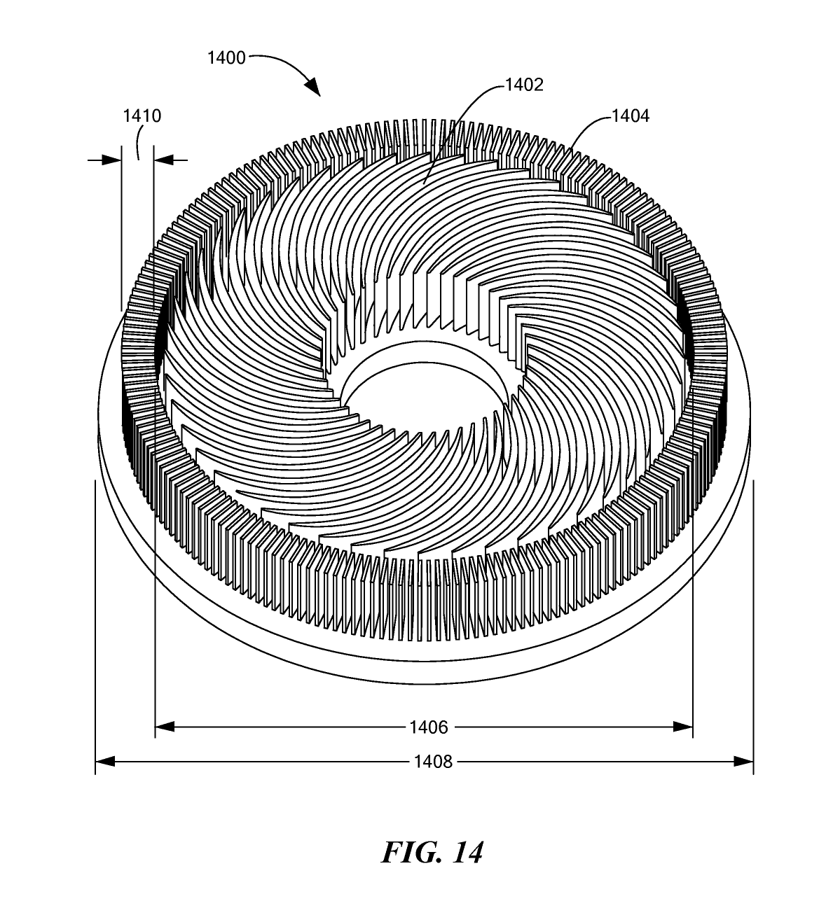

FIG. 13 illustrates the relative velocity of fluid flow within the kinetic heat sink and stationary fins of the embodiment of FIGS. 7 and 14. As indicated, as fluid is drawn in from the top of the impeller and flows over the length of the channel (corresponding to region 1302), the relative velocity 1306 of the fluid increases as a result of conservation of mass. Similarly, as the fluid radially flows from the impeller 702 to the stationary fins 714, the velocity decreases due to conservation of mass. Generally, the channels of the stationary fins 714 have diverging cross-sectional areas. Thus, as the fluid travels past increasing cross-section areas, the velocity of the fluid decreases. Consequently, the velocity profile (i.e., distribution) across the stationary fins (corresponding to region 1304) may be shaped based on the geometry and placement of the stationary fins 714. The fluid exits the kinetic heat sink 700 at an output flow velocity 1308.

The housing may be configured to produce a particular relative velocity profile of the fluid flow. For example, in an embodiment, the top portion of the kinetic heat sink may be completely opened to allow the fluid to enter in the middle of the kinetic heat sink. The housing and impeller maybe spaced apart with a small clearance thereby forcing the fluid to flow only through the middle of the impeller at the beginning of the fins and then through the entire length of the fins.

Alternatively, the housing may be configured to allow the fluid to enter along the length of the channels. For example, the housing of the kinetic heat sink may be configured to allow the fluid to enter, rather than just at the beginning, along the channels of the impeller and the stationary fins. The housing may, for example, include several channel located at different radial position. Alternatively, the housing may also be configured with a larger clearance between the housing and impeller to allow fluid to enter along the length of the channels. Although the fluid may enter at a later section of the impeller, thus having reduced area for thermal transfer, the configuration may result in a more efficient thermal transfer in total. This effect may be attributed to the fluid velocity being increased in the later portion of the channel due to more fluid being in the channel. This effect may also be attributed to the configuration having a lower resistance to flow, which allows for a higher fluid velocity.

In another aspect of the embodiments, the impeller or the stationary fins may be configured, in addition to or in lieu of, to produce a particular relative velocity profile of the fluid flow. For example, the impeller or the stationary fins may be configured with fins that form channels therebetween having a constant-area profile along the length of the channel. As such, if fluid enters the impeller or the stationary fins only at the beginning of the channel, the velocity of the fluid remains relatively constant across the channel.

In another embodiment, the channels may be configured to have a diverging profile or converging profile along the length of the channel. As compared with a constant width channel, the velocity of a diverging channel would decreases as the cross-sectional area of the channel becomes larger. With converging channels, the velocity of the fluid may increase as the fluid travels through the converging section.

With regard to the fluid gap, although thermal resistance usually decreases with increasing rotational speed, the heat generated by the fluid gap shearing also increases. As a result, the effective thermal resistance of the fluid gap may increase at too high of a rotational speed.

In accordance with another embodiment of the invention, a method of operating a heat-dissipating apparatus is provided.

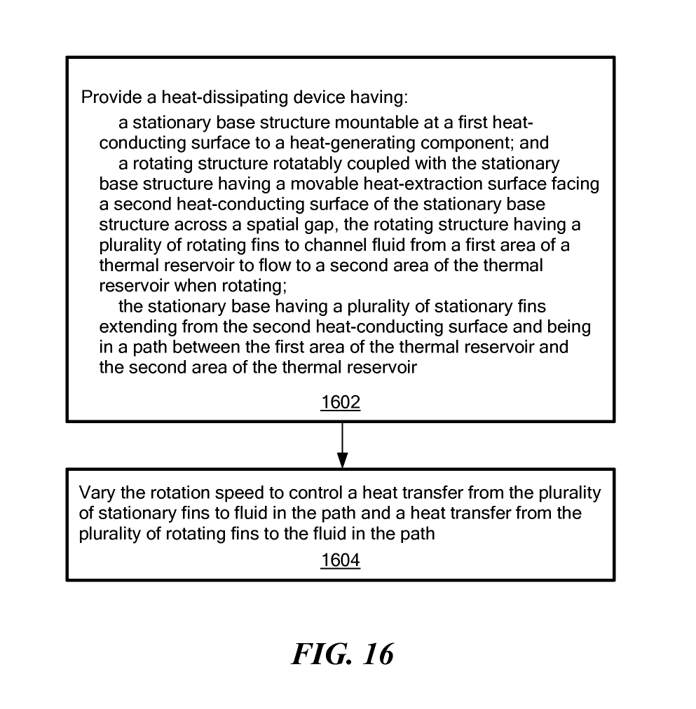

FIG. 16 shows a method of operating a kinetic heat sink according to an illustrative embodiment. The method provides a heat-dissipating apparatus having a base structure, a rotating structure, and stationary fins (step 1602). The base structure has a first heat-conducting surface and a second heat-conducting surface to conduct heat therebetween. The first heat-conducting surface is mountable to a heat-generating component. The rotating structure rotatably couples with the base structure and has a movable heat-extraction surface facing the second heat-conducting surface across a fluid gap. The rotating structure has rotating fins that channels a heat-transfer fluid when the rotating structure rotates from a region (i.e., first area) of a thermal reservoir in communicating with the rotating structure to another area (i.e., second area) of the thermal reservoir. The stationary fins extend from the second heat-conducting surface or the housing and in the path of fluid flow between the first area and the second area of the thermal reservoir.

The method also varies the speed of rotation of the rotating structure to control an amount of heat transfer from the stationary fins in the path of the fluid flow and the heat transfer from the rotating fins (step 1604). For example, the method may maximize Qₜₒₜₐₗ of Equation 3 or 4. The controls may be based on models of the thermal-resistance characteristics of a kinetic heat sink as illustrated in FIG. 9.

In having an alternate channel for dissipating heat, the kinetic heat sink with stationary fins may additionally improve response time of the controls of the kinetic heat sink. The high inertia of the kinetic heat sink maintains the speed of the kinetic heat sink. However, as thermal loads from the heat-generating source vary, the inertia delays the kinetic heat sink in reacting to the load. The stationary fins provide an alternate control point having less inertia as the kinetic portion of the heat sink.

FIG. 14 is a schematic illustrating a kinetic heat sink with stationary fins according to an embodiment. The kinetic heat sink apparatus 1400 includes a set of rotating fins 1402 and a set of stationary 1404. The set of stationary fins may be adapted to increase the surface area for heat transfer by over 20 percent. The set of rotating fins 1402 includes forty-two (42) backward curved fins having a span 1406 nearly 86% of the span 1408 of the apparatus 1400. The set of stationary fins 1404 includes two-hundred (200) straight-radial fins that span nearly 14 percent of the outer circumferential span 1410 of the apparatus 1400. The set of stationary fins 1404 may increase thermal-resistance performance by more than 30% compared to a kinetic heat sink of comparable size without stationary fins. The kinetic heat sink apparatus 1400 may have a thermal resistance of 0.2 C/W at 5 Watt of energy draw for the motor. The set of stationary fins have a cross-section area equal to the cross-section area of the channels formed between each of the stationary fins. FIG. 13 shows an exemplary velocity profile of the kinetic heat sink of FIG. 14.

In an embodiment, the kinetic heat sink may have a total outer diameter of 8.89 cm (3.5 inches). The set of rotating fins 1402 may have a diameter of 7.62 cm (3 inches). The set of stationary fins may have a length of 1.016 cm (0.4 inches) and have a constant cross-sectional area of 0.5 mm, which forms a channel of 0.5 mm to adjacent stationary fins. The set of rotating fins 1402 may have a surface area of 43 cm², which accounts for 61% of the surface area, while the set of stationary fins 1404 has a surface area of 28 cm², which accounts for 39% of the surface area, to provide a total surface area of 72 cm². When compared to a backward-curved kinetic heat sink that does not have stationary fins (referred to as “Sigmatec”), which has a surface area of 59 cm², the kinetic heat sink apparatus 1400 has a surface area more than 20% greater. Here, the fluid gap has a thermal resistance of 0.11 C/W, and the baseplate has a thermal resistance of 0.029 C/W, which includes the thermal resistance of the set of stationary fins 1404. Of course, other dimensions and ratios thereof may be employed.

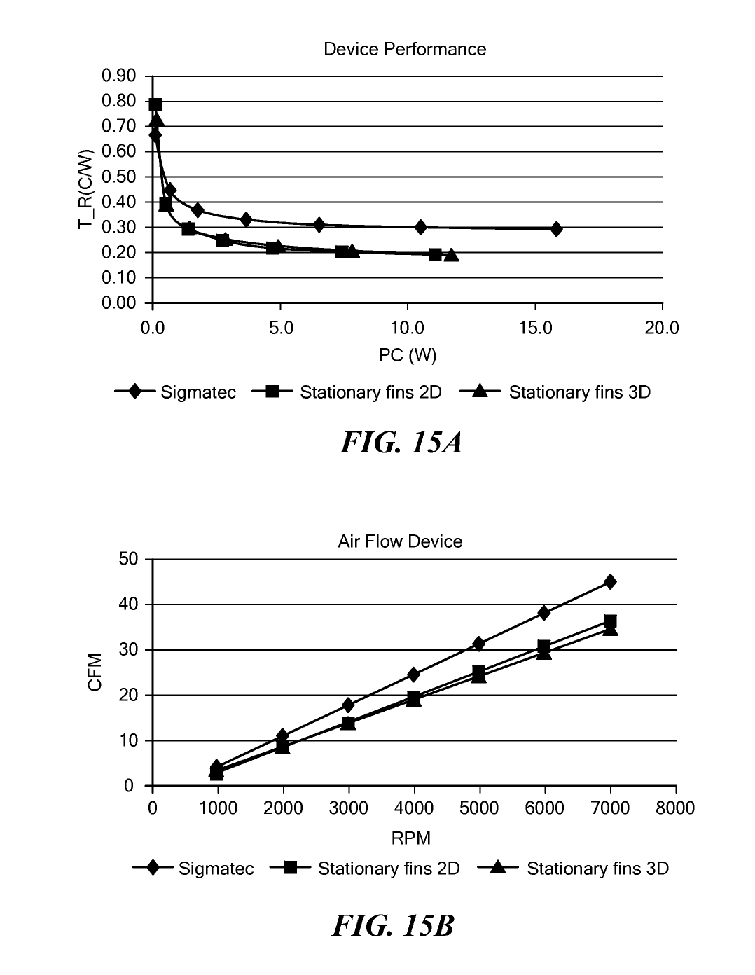

FIG. 15A is a plot illustrating device performance of the kinetic heat sink apparatus 1400 of FIG. 14. A computational fluid-dynamic analysis of the kinetic heat sink shown in FIG. 14 is provided. The analysis is performed using a two-dimensional model and a three-dimensional model of the kinetic heat sink with stationary fins. The results are compared to a base-line kinetic heat sink of comparable diameter size, but without the stationary fins. FIG. 15B is a plot illustrating volumetric fluid flow of the kinetic heat sink apparatus 1400 of FIG. 14. Table 1 provides the numerical results of FIGS. 15A and 15B for different rotation speed of the kinetic heat sink apparatus 1400 between 1,000 RPM and 7,000 RPM. The labels “stationary fins 2D” and “stationary fins 3D” refer to the kinetic heat sink apparatus 1400 of FIG. 14 in its entirety, including the set of rotating fins 1402 and the set of stationary 1404, among other components described above, while the label “Sigmatec” refers to a kinetic heat sink of comparable size without stationary fins.

TABLE 2

| | | | | Stationary fins | | | | | | |
|---|---|---|---|---|---|---|---|---|---|---|
| Sigmatec | | | | | T_R | PC | | T_R | PC | |
| | T_R | PC | | | (C/W) | (W) | CFM | (C/W) | (W) | CFM |
| RPM | (C/W) | (W) | CFM | RPM | 2D | 2D | 2D | 3D | 3D | 3D |
| 1000 | 0.66 | 0.1 | 3.9 | 1000 | 0.78 | 0.1 | 2.9 | 0.73 | 0.1 | 3.2 |
| 2000 | 0.45 | 0.7 | 10.6 | 2000 | 0.39 | 0.5 | 7.9 | 0.39 | 0.6 | 8.3 |
| 3000 | 0.37 | 1.8 | 17.4 | 3000 | 0.29 | 1.4 | 13.4 | 0.30 | 1.4 | 13.6 |
| 4000 | 0.33 | 3.7 | 24.2 | 4000 | 0.25 | 2.8 | 19.0 | 0.25 | 2.8 | 18.9 |
| 5000 | 0.31 | 6.5 | 30.9 | 5000 | 0.22 | 4.8 | 24.6 | 0.23 | 4.9 | 24.1 |
| 6000 | 0.30 | 10.5 | 37.7 | 6000 | 0.20 | 7.5 | 30.2 | 0.21 | 7.8 | 29.3 |
| 7000 | 0.29 | 15.8 | 44.5 | 7000 | 0.19 | 11.0 | 35.7 | 0.19 | 11.7 | 34.5 |

The embodiments of the invention described above are intended to be merely exemplary; numerous variations and modifications will be apparent to those skilled in the art. All such variations and modifications are intended to be within the scope of the present invention as defined in any appended claims.

What is claimed is:

1. A heat-dissipating apparatus comprising:
a base structure having a first heat-conducting surface and a second heat-conducting surface to conduct heat therebetween, the base structure being mountable at the first heat-conducting surface to a heat-generating component; and
a rotating structure rotatably coupled with the base structure, the rotating structure having a movable heat-extraction surface facing the second heat-conducting surface across a fluid gap, the rotating structure having a plurality of moving fins configured to move fluid,
the base structure having a plurality of stationary fins extending from the second heat-conducting surface, the plurality of stationary fins being positioned to contact the fluid moved by the plurality of moving fins.

2. The heat-dissipating apparatus of claim 1 further comprising:
a housing having an inlet and an outlet along a path, the housing being fixably coupled to the base structure.

3. The heat-dissipating apparatus of claim 2, wherein the housing encloses the rotating structure and the plurality of stationary fins.

4. The heat-dissipating apparatus of claim 3 further comprising:
a plurality of external stationary fins extending from the second heat-conducting surface outside of the housing, the plurality of external stationary fins being in the path between a first area and a second area of a thermal reservoir in communication with the heat-dissipating apparatus.

5. The heat-dissipating apparatus of claim 3 further comprising:
a plurality of external stationary fins extending from the at least one of the inlet and the outlet of the housing, the plurality of external stationary fins being in the path between a first area and a second area of a thermal reservoir in communication with the heat-dissipating apparatus.

6. The heat-dissipating apparatus of claim 2, wherein the housing is generally shaped as at least one of a spiral and a shell.

7. The heat-dissipating apparatus of claim 2, wherein the housing is generally shaped as a nautilus shell.

8. The heat-dissipating apparatus of claim 1, wherein the plurality of stationary fins is generally shaped as a blade, a peg, and a cylinder.

9. The heat-dissipating apparatus of claim 1, wherein the plurality of stationary fins extends equally apart from the second heat-conducting surface in a grid pattern.

10. The heat-dissipating apparatus of claim 1, wherein the plurality of stationary fins extends asymmetrically apart from the second heat-conducting surface in a grid pattern.

11. The heat-dissipating apparatus of claim 1, wherein the rotating structure forms an impeller.

12. The heat-dissipating apparatus of claim 1, wherein the plurality of stationary fins are shaped to minimize noise.

13. The heat-dissipating apparatus of claim 1, wherein the apparatus has a heat-transfer coefficient greater than 150 W/(m² K).

14. The heat-dissipating apparatus of claim 1, wherein the rotating structure rotates in a manner to cause 30 CFM of fluid flow.

15. The heat-dissipating apparatus of claim 1, wherein the rotating structure dissipates heat from the plurality of moving fins when moving the fluid, and the plurality of stationary fins dissipating heat when in contact with the fluid moved by the plurality of moving fins.

16. A method of operating a heat-dissipating apparatus, comprising:
providing a heat-dissipating device having:
a base structure having a first heat-conducting surface and a second heat-conducting surface to conduct heat therebetween, the base structure being mountable at the first heat-conducting surface to a heat-generating component; and
a rotating structure rotatably coupled with the base structure, the rotating structure having a movable heat-extraction surface facing the second heat-conducting surface across a fluid gap, the rotating structure having a plurality of rotating fins configured in a manner to cause fluid to flow when moving;
the base further having a plurality of stationary fins extending from the second heat-conducting surface, the plurality of stationary fins being positioned to contact the fluid moved by the moving fins;
energizing the heat-dissipating device to rotate the rotating structure; and
varying a rotating speed of the rotating structure to vary a heat transfer from the plurality of stationary fins to fluid in a path and a heat transfer from the plurality of rotating fins to the fluid in the path.
